(19) United States
(12) Patent Application Publication
(10) Pub. No.: US 2001/0054906 A1
(43) Pub. Date: Dec. 27, 2001

(54) Probe card and a method of manufacturing the same

(76) Inventor: Naoyuki Fujimura, Tokyo (JP)

Correspondence Address: FLYNN, THIEL, BOUTELL & TANIS, P.C., 2026 Rambling Road, Kalamazoo, MI, 49008-1699, US

(21) Appl. No.: 09/875,067

(22) Filed: Jun. 6, 2001

(30) Foreign Application Priority Data
Jun. 21, 2000 (JP) 2000-186584

(51) Int. Cl. G01R 31/02

(52) U.S. Cl. 324/754

(57) ABSTRACT

In a probe card for testing a plurality of semiconductor integrated circuits formed on a semiconductor wafer in a lump, only a faulty probe can be repaired without removing all probes from a wiring board. The probe card comprises a plurality of probes to be connected to respective testing electrodes formed on the semiconductor wafer, and wiring means provided with pads to be jointed to the probes, wherein the pads is formed on the upper surface of the wiring board.

### BACKGROUND OF THE INVENTION

1. Field of the Invention

The invention relates to a probe card for use in testing the excitation or the like of all the semiconductor integrated circuits formed on a semiconductor wafer at the same time in a state of wafer and a method of manufacturing the same.

2. Related Art

The miniaturization of electronic devices has been recently remarkably developed, and the demand for miniaturization of semiconductor integrated circuits to be mounted on the electronic devices has increased. To meet such demand, there is developed a method of mounting the semiconductor integrated circuits directly on a circuit substrate or board in a state where the semiconductor integrated circuits are cut from a semiconductor wafer, namely, in a state of bare chips. Accordingly, it is desired to supply bare chips which are guaranteed in quality.

All the semiconductor integrated circuits need to be subjected to a burn-in screening in a state of bare chips so as to guarantee the quality of bare chips. It is required that the semiconductor integrated circuits are subjected to a burn-in screening in a lump in a state of wafer, namely, before bare chips are cut from the wafer.

In order to allow the semiconductor chips to be subjected to a burn-in screening in a lump in a state of wafer, it is necessary to apply a power supply voltage, a signal and so forth at the same time to a plurality of chips formed on the same wafer so as to operate the plurality of chips. Although it is required to prepare a probe card having several thousands of probes or more in order to meet the requirement, there is a problem that a conventional needle type probe card cannot cope with this requirement in view of the number of pins and the cost thereof.

Accordingly, there is proposed a probe card wherein a minute spring is formed on a board by use of wire bonding and which is disclosed in Japanese Patent Laid-Open Publication Nos. 10-506197 and 2000-67953 as shown in FIG. 3.

In FIG. 3, depicted by 210 is a probe, 212 is a board, 214 is a terminal, 216 is a wire core, 218 is an inner layer and 220 is an outer layer. The wire core 216 is normally made of a soft metal such as gold to be used in a wire bonding and is formed on the terminal 214 provided on the board 212 by a wire bonding and is cut to form a spring shape.

When plating is applied to the wire core 216, the inner layer 218 and the outer layer 220 are formed. The inner layer 218 is made of a hard material to have resiliency and the outer layer 220 is made of a material which is excellent in oxidation resistant property and conductivity.

Inasmuch as all the probes of this probe card are formed when plating is applied thereto at a time after they are made of a soft metal by wire bonding, there occurs a problem that only faulty portions of the probes can not be repaired partially when some probes of already formed several thousand probes are rendered faulty or partial faults occur in the probes when the probes are repeatedly used. Accordingly, it is required that after all probes are removed from the board, they are formed from the beginning.

### SUMMARY OF THE INVENTION

The invention has been developed in view of the foregoing circumstances, and it is an object of the invention to provide a probe card for testing a wafer in a lump capable of repairing faulty probes without removing all the probes from a board.

To achieve the above object, the probe card according to a first aspect of the invention for testing a probe card for testing all the semiconductor integrated circuits formed on a semiconductor wafer at the same time, for example, as shown in FIG. 1, comprises a plurality of connection members 3 to be connected to respective testing electrodes formed on the semiconductor wafer, and wiring means 1 electrically connected to the connection members 3, wherein the connection members 3 are jointed to junction sections 2 formed on the wiring means 1.

The connection members defined in the specification may be formed of anything if they serve to connect between the wiring means and the semiconductor integrated circuits so that a power supply voltage, a signal and so forth can be simultaneously applied from the wiring means to the plurality of semiconductor integrated circuits, and hence they are formed of, for example, probes.

Wiring means are means for wiring such as a wiring board or the like for applying a power supply voltage, a signal or the like to each semiconductor integrated circuit so as to render each semiconductor integrated circuit conductive.

The junction sections 2 defined in the specification may be anything if they have electric conductivity and serve to joint the junction sections 2 by use of soldering or the like, and hence they are formed of, for example, metallic pads.

According to the first aspect of the invention, since the probe card is provided with the connection members 3 and the wiring means 1 wherein the connection members 3 are jointed to junction sections 2 formed on the wiring means 1, when the probe card is used repetitively, or owing to other reasons, some connection members 3 are rendered faulty, only the faulty connection members 3 can be removed with ease, and new connection members 3 can be jointed to the junction sections 2 with ease.

Accordingly, only the faulty connection members 3 can be repaired per unit without removing all the connection members 3 from the wiring means 1.

It is a second aspect of the invention to provide the probe card set forth in the first aspect of the invention, wherein the connection members 3 are jointed to the junction sections 2 by soldering, for example, as shown in FIG. 2.

According to the second aspect of the invention, since it is the probe card set forth in the first aspect of the invention, wherein the connection members 3 are jointed to the junction sections 2 by soldering, so that the connection members 3 can be jointed to the junction sections 2 with assurance.

It is a third aspect of the invention to provide the probe card set forth in the first or second aspect of the invention, wherein the connection members 3 are formed by rendering a hard metal in a given shape and by applying plating thereto.

As example of hard metals, metal such as nickel, chromium, iron or an alloy having a main composition thereof is exemplified.

According to the third aspect of the invention, since it is the probe card set forth in the first or second aspect of the invention, wherein the connection members 3 are formed by rendering a hard metal in a given shape and by applying plating thereto, which is different from connection members formed of metal such as gold by wire bonding to which plating is applied, even if the connection members 3 are rendered faulty partially, only the faulty connection members 3 can be partially repaired.

It is a fourth aspect of the invention to provide the probe card set forth in the first, second or third aspect of the invention, wherein each of the connection member 3 has a structure to be elastically deformed.

According to the fourth aspect of the invention, since it is the probe card set forth in the first, second or third aspect of the invention, wherein each connection member 3 has a structure to be elastically deformed, a pressure generated when the semiconductor integrated circuits and the connection members 3 contact each other under pressure can be sufficiently absorbed by the connection members 3. Accordingly, the connection members 3 can absorb a pressure more than necessary so that the connection members 3 can contact the semiconductor integrated circuits under an appropriate pressure.

It is a fifth aspect of the invention to provide the probe card set forth in the fourth aspect of the invention, wherein each of the connection members 3 has substantially an S-shaped configuration.

According to the fifth aspect of the invention, since it is the probe card set forth in the fourth aspect of the invention, wherein each of the connection members 3 has substantially an S-shaped configuration, the connection members 3 can sufficiently absorb not only a pressure caused by contact under pressure but also a force exerting perpendicularly to a pressure application direction.

A method of manufacturing a probe card according to a sixth aspect of the invention for testing a plurality of semiconductor integrated circuits formed on a semiconductor wafer, for example, as shown in FIG. 2, comprising the steps of forming connection members 3 to be connected to respective testing electrodes formed on the semiconductor wafer, jointing the connection members 3 with the junction sections 2 formed on wiring means 1.

According to the sixth aspect of the invention, since it is the method of manufacturing the probe card comprising the step of forming the connection members and the step of jointing the connection members with the junction section, the connection members can be formed per unit in a state where they are not jointed to the wiring means, and the connection members can be jointed to the junction sections per unit. Accordingly, the faulty connection members can be replaced with others or can be repaired per unit.

### BRIEF DESCRIPTION OF THE DRAWINGS

FIG. 1 is a partially perspective view showing a probe card as an example to which the invention is applied;

FIG. 2 is a view showing a step of jointing probes to the probe card in FIG. 1; and

FIG. 3 is a partially sectional view showing the construction of a conventional probe card.

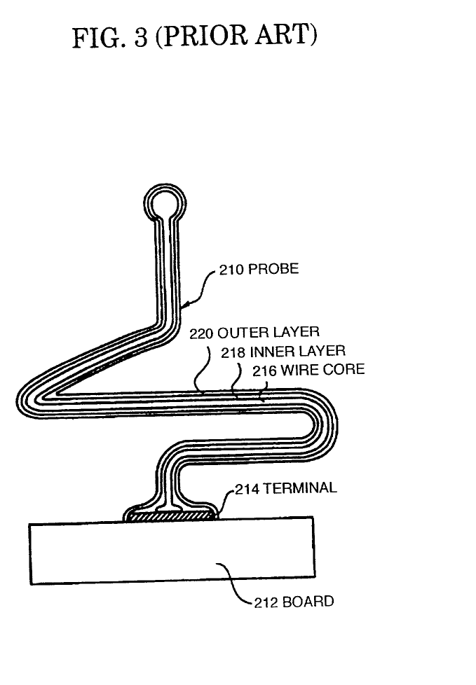

### PREFERRED EMBODIMENT OF THE INVENTION

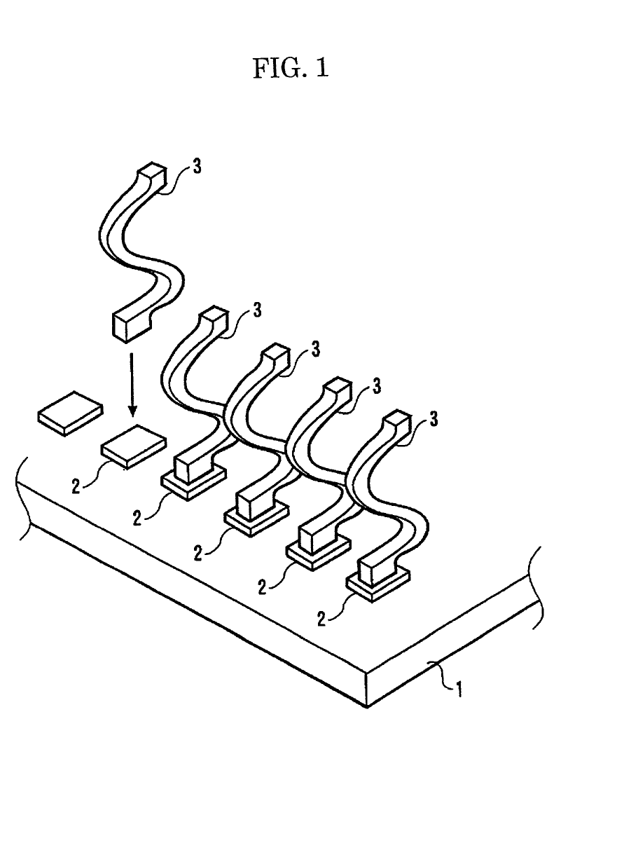

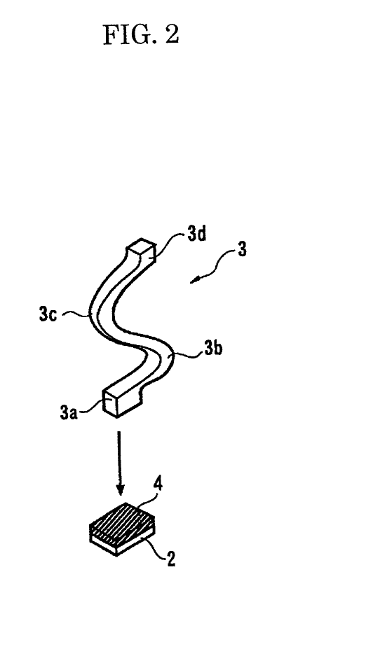

A probe card and a method of manufacturing the same according to a preferred embodiment of the invention are described with reference to FIGS. 1 and 2. FIG. 1 is a partially perspective view showing a probe card as an example to which the invention is applied. FIG. 2 is a view showing a step of jointing probes to the probe card in FIG. 1. In these figures, depicted by 1 is a wiring board (wiring means), 2 is pads (junction sections), 3 is probes (connection members) and 4 is solder.

The wiring board 1 has a plurality of wires (leads) so as to apply a power supply voltage, a signal and so forth to a plurality of semiconductor integrated circuits at the same time for testing excitation of the semiconductor integrated circuits formed on a semiconductor wafer. Further, a plurality of (e.g., several thousands of) pads 2 are formed on the surface of the wiring board 1 as shown in FIG. 1, wherein respective wires are connected to corresponding pads 2 so that the excitation test can be effected appropriately.

The pads 2 are to be jointed to the probes 3, described later, and formed by coating the surface of the wiring board 1 with a metallic layer. The pads 2 are formed at positions corresponding to a plurality of semiconductor integrated circuits so that the semiconductor integrated circuits formed on the semiconductor wafer can be easily tested at a time.

The probes 3 are brought into contact with under pressure respective testing electrodes formed on the semiconductor wafer for supplying a signal and so forth outputted from the wiring board 1 to respective semiconductor integrated circuits. As shown in FIG. 2, each probe 3 comprises a pad junction section 3a to be jointed to each pad 2, two bent sections 3b, 3c, and a pressure contact section 3d for bringing into contact under pressure with each semiconductor integrated circuit formed on the semiconductor wafer. The pad junction section 3a is flat at the bottom surface so that it can be easily jointed to each pad 2 and is formed thick so as to protrude downward compared with an intermediate section between the pad junction section 3a and the bent section 3b. The two bent sections 3b, 3c are bent to protrude in opposite directions. The pressure contact section 3d is flat at the upper surface and is formed to protrude upward so as to bring into contact under pressure with each semiconductor integrated circuit with ease. The width of each probe 3 is gradually narrowed in the direction from the bent section 3b toward the bent section 3c, and it is the narrowest at the bent section 3c. Further, the width of each probe 3 is gradually widened in the direction from the bent section 3c toward the pressure contact section 3d. As a result, each probe 3 has a substantially S-shaped configuration.

Each probe 3 is formed by applying metallic plating such as electrolytic or electroless plating as anti-oxidation measure after it was formed of a hard metal such as nickel or alloy.

Since the probe 3 has the foregoing configuration, and is formed by a hard metal, each probe 3 is elastically deformed when an external force is applied thereto. That is, since each probe 3 has an elasticity, a pressure acting perpendicularly onto a contact surface between itself and a semiconductor circuit on the semiconductor wafer when they are brought into contact with each other is absorbed by each probe 3 when it is elastically deformed. Accordingly, each probe 3 can absorb a pressure than necessary so that the each probe 3 can contact the semiconductor circuit at an appropriate pressure. Further, since each probe 3 has the foregoing configuration, it can absorb a force acting perpendicularly to the foregoing pressure. As a result, a contact surface between the pressure contact section 3d of the each probe 3 and each semiconductor integrated circuit is not displaced.

Next, a method of jointing each probe to the probe card is now described.

First, as shown in FIG. 2, an appropriate amount of solder 4 is applied onto each pad 2 on the wiring board 1 and the solder 4 is melted by use of heating means such as a soldering iron (not shown). Hard metals are molded in advance as set forth above, and a plating is applied to the hard metals to form the probes 3 individually, and the probes 3 are held by holding means (not shown), then the probes probe 3 are lowered while they are controlled in a position, inclination, height and so forth to contact the solder 4. Thereafter, the operation of the heating means is stopped after confirmation of the position, inclination, height and so forth of each probe 3, each probe 3 is allowed to joint to each pad 2. At this time, the probes 3 may be jointed to the pads 2 one by one or by a plurality of numbers in a lump.

When the probes is rendered faulty in part, the faulty probe 3 can be repaired in the following manner. First, the hard metals are molded in the foregoing configuration by the number of faulty probes, and metallic plating was applied to the hard metals to form the probes 3. Then, only the faulty probes 3 are removed from the pads 2 on the wiring board 1, and the newly formed probes 3 are jointed to the pads 2 by soldering. As a result, the probes 3 can be formed one by one, and even if the probes are rendered faulty in part, the faulty probes 3 can be replaced with new ones or repaired per unit.

As mentioned above, since the probes 3 are jointed to the pads 2 formed on the wiring probes board 1, in the case that the probe card is repetitively used or the like when the probes 3 are rendered faulty in part, only the faulty probe can be removed from the corresponding pad 2 with ease, and a newly formed probe 3 can be jointed to the corresponding pad 2 with ease. As a result, only the faulty probe 3 can be repaired per unit without removing all the probes 3 from the wiring board 1.

Since each probe 3 is jointed to the corresponding pad 2 after it was formed, so that each probe 3 can be formed per unit, and even if probes 3 is rendered faulty in part, when the probe card is used repetitively or the like, only the faulty probe 3 can be replaced with a new one or repaired per unit.

In the preferred embodiment set forth above, although a hard metal comprises nickel or an alloy thereof, the invention is not limited to nickel or an alloy thereof but other metals may be used. It is a matter of course that other detailed constrictions or the like of the probe card can be suitably changed.

According to the first aspect of the invention, since the probe card is provided with the connection members and the wiring means wherein the connection members are jointed to junction sections formed on the wiring means, in the case where some connection members are rendered faulty when the probe card is used repetitively, or owing to other reasons, only the faulty connection members can be removed with ease, and new connection members can be jointed to the junction sections with ease, there is an advantage that only the faulty connection members can be repaired per unit without removing all the connection members from the wiring means.

According to the second aspect of the invention, since the connection members are jointed to the junction sections by soldering, there is an advantage in addition to the effect obtained by the first aspect of the invention, that the connection members can be jointed to the junction sections with assurance.

According to the third aspect of the invention, since the connection members are formed by rendering a hard metal in a given shape and by applying plating thereto, even if the connection members become faulty in part, only the faulty connection members can be partially repaired, which is different from connection members formed of metal such as gold by wire bonding to which plating is applied.

According to the fourth aspect of the invention, since a pressure generated when the semiconductor integrated circuits and the connection members contact each other under pressure can be sufficiently absorbed by the connection members when it is elastically deformed, there is advantage, in addition to the advantage obtained by the first, second or third aspect of the invention, that the connection members can absorb a pressure more than necessary so that the connection members can contact the semiconductor integrated circuits under appropriate pressure.

According to the fifth aspect of the invention, since it is the probe card set forth in the fourth aspect of the invention, wherein each of the connection members 3 has substantially an S-shaped configuration, the connection members 3 can sufficiently absorb not only a pressure caused by contact under pressure but also a force exerting perpendicularly to a pressure application direction.

According to the sixth aspect of the invention, since the connection members can be formed per unit in a state where they are not jointed to the wiring means per unit, and the connection members can be jointed to the junction sections per unit. Accordingly, the faulty connection members can be replaced with others or can be repaired per unit by the steps of forming the connection members and the step of jointing the connection members to the junction section, there is an advantage that the faulty connection members can be replace with others or can be repaired per unit.

What is claimed is:

1. A probe card for testing a plurality of semiconductor integrated circuits formed on a semiconductor wafer comprising:
a plurality of connection members to be connected to testing electrodes formed on the semiconductor wafer; and
wiring means electrically connected to the connection members;
wherein the connection members are jointed to junction sections formed on the wiring means.

2. The probe card according to claim 1, wherein the connection members are jointed to the junction sections by soldering.

3. The probe card according to claim 1 or 2, wherein the connection members are formed by rendering a hard metal in a given shape and by applying plating thereto.

4. The probe card according to claim 1, 2 or 3, wherein each of the connection member has a structure to be elastically deformed.

5. The probe card according to claim 4, wherein each of the connection members has substantially an S-shaped configuration.

6. A method of manufacturing a probe card for testing a plurality of semiconductor integrated circuits formed on a semiconductor wafer comprising:
a step of forming a plurality of connection members to be connected to testing electrodes formed on the semiconductor wafer; and
a step of jointing the connection members with the junction sections formed on wiring means.
